(19) United States
(12) Patent Application Publication
(10) Pub. No.: US 2004/0124541 A1
(43) Pub. Date: Jul. 1, 2004

(54) Flip chip package

(76) Inventors: Sung Mao Wu, Kaohsiung (TW); Hsueh Te Wang, Kaohsiung (TW); Chi Pin Hung, Kaohsiung (TW)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/681,445

(22) Filed: Oct. 8, 2003

(30) Foreign Application Priority Data
Dec. 31, 2002 (TW) 091138206

(51) Int. Cl. H01L 23/48

(52) U.S. Cl. 257/778

(57) ABSTRACT

A flip chip package mainly includes a semiconductor chip disposed in a recessed cavity defined in an upper surface of a substrate by flip chip bonding. The lower surface of the substrate is provided with a reinforcement-containing insulating layer thereby enhancing mechanical strength thereof. The upper surface of the substrate is provided with a plurality of solder pads formed at the periphery of the recessed cavity for making external electrical connections. The substrate includes a plurality of chip contact pads provided on the surface of the reinforcement-containing insulating layer and exposed from the recessed cavity wherein the chip contact pads are electrically connected to the solder pads through a plurality of conductive traces.

### BACKGROUND OF THE INVENTION

1. Field of the Invention

This invention relates to a semiconductor device, and more specifically to a flip chip package.

2. Description of the Related Art

As electronic devices have become smaller and thinner, the velocity and the complexity of IC chip become higher and higher. Accordingly, a need has arisen for higher package efficiency. Demand for miniaturization is the primary catalyst driving the usage of advanced packages such as chip scale packages (CSP) and flip chips. Both of them greatly increase the package efficiency thereby reducing the amount of board real estate required when compared to the alternative ball grid array (BGA) or thin small outline package. Typically, a CSP is 20 percent larger than the die itself, while the flip chip has been described as the ultimate package precisely because it has no package. The bare die itself is attached to the substrate by means of solder bumps directly attached to the die.

FIG. 1 discloses a conventional flip chip package 100 including a semiconductor chip mounted to an upper surface of a substrate 120 by the flip chip technique. The substrate 120 is typically formed from a reinforcement-containing core layer 121 thereby enhancing mechanical strength thereof. The bonding pads on the upper surface of the chip 110 are connected to the conductive traces 123 disposed on the upper surface of the substrate 120 by solder joints 112. The lower surface of the substrate 120 is provided with a plurality of solder pads 125 electrically connected to the conductive traces 123 on the upper surface of the substrate 120 by conductive traces and plated through-holes 129. Each solder pad 125 is provided with a solder ball 140 for making external electrical connections.

The plated through-holes 129 are typically formed by drilling through-holes on the core layer 121, and coating a layer of conductive metal to the through-holes. However, so far as the multilayer substrate is concerned, a major factor to limit pattern density is the through-holes and their pads. Pad diameter is generally larger than drill diameter by 0.2 mm so to compensate for the drill misregistration, laminate expansion/shrinkage and photo tool expansion/shrinkage. Therefore, it is quite difficult to have a high pattern density in the multilayer substrate mentioned above.

The core layer 121 typically has a relatively large thickness so as to significantly reduce the likelihood of warpage. However, the thicker the core layer is, the longer the plated through-holes become. This will adversely affect the electrical performance of the final package, since the impedance, the inductance and the noise of the plated through-holes are in proportion to the length of the plated through-holes. Moreover, the high inductance makes package consume more electricity such that the integrated circuit and traces inside the chip are more susceptible to power surges.

### SUMMARY OF THE INVENTION

It is an object of the present invention to provide a flip chip package which overcomes, or at least reduces the above-mentioned problems of the prior art.

A flip chip package according to the present invention mainly includes a semiconductor chip disposed in a recessed cavity defined in a substrate by flip chip bonding. The lower surface of the substrate is provided with a reinforcement-containing insulating layer thereby enhancing mechanical strength thereof. The upper surface of the substrate is provided with a plurality of solder pads formed outside the recessed cavity for making external electrical connections. The substrate includes a plurality of chip contact pads provided on the surface of the reinforcement-containing insulating layer and exposed from the recessed cavity wherein the chip contact pads are electrically connected to the solder pads through a plurality of conductive traces. Specifically, the semiconductor chip is mechanically and electrically interconnected to chip contact pads on the insulating layer of the substrate via solder balls, column-like solder bumps or anisotropic conductive adhesive film (ACF).

It is noted that the conductive traces of the flip chip package according to the present invention for electrically connecting the chip contact pads to the solder pads are all formed on the same side of the reinforcement-containing insulating layer. Therefore, the flip chip package of the present invention doesn't need to be provided with any plated through-hole in the reinforcement-containing insulating layer thereby reducing the length of the conductive traces required in the substrate so as to improve the electrical performance of the final package. Moreover, the pattern density of the substrate according to the present invention is not limited by the plated through-holes thereby increasing the degree of freedom in designing the substrate circuit layout.

The flip chip package according to the present invention may further include a metal coating formed on the lower surface of the substrate (i.e. the surface of the reinforcement containing insulating layer) and a plurality of conductive vias formed through the reinforcement-containing insulating layer. Furthermore, the flip chip package according to the present invention may include a heat sink disposed on the backside surface of the semiconductor chip.

Other objects, advantages, and novel features of the invention will become more apparent from the following detailed description when taken in conjunction with the accompanying drawings.

### BRIEF DESCRIPTION OF THE DRAWINGS

FIG. 1 is a cross sectional view of a conventional flip chip package;

FIG. 2 is a cross sectional view of a flip chip package according to one embodiment of the present invention; and

FIG. 3 is a cross sectional view of a flip chip package according to another embodiment the present invention.

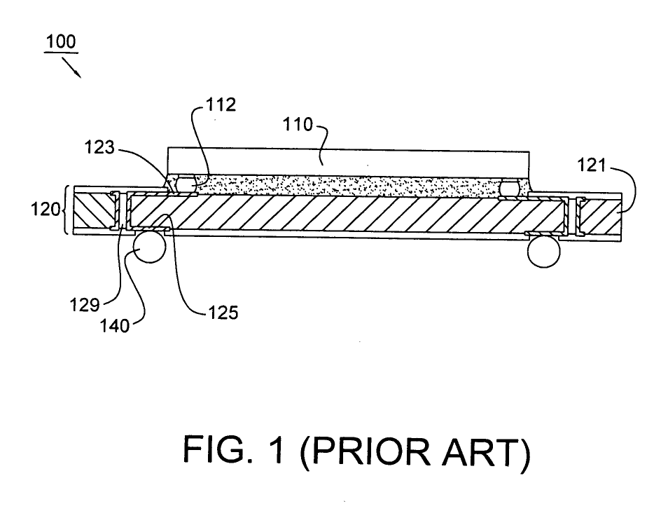

### DETAILED DESCRIPTION OF THE PREFERRED EMBODIMENT

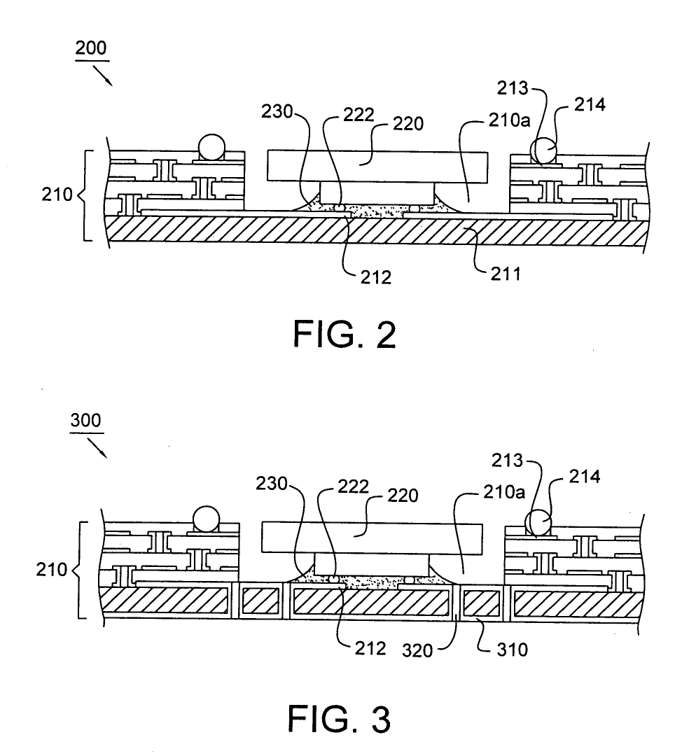

FIG. 2 illustrates a flip chip package 200 according to one embodiment of the present invention. The flip chip package 200 mainly includes a substrate 210 for supporting and electrically connecting to a semiconductor chip 220. The substrate 210 has a recessed cavity defined in the upper surface of the substrate for receiving the semiconductor chip 220. The substrate has a reinforcement-containing insulating layer for enhancing the mechanical strength of the substrate 210, and a plurality of chip contact pads 212 formed on the surface of the insulating layer 211 and exposed from the recessed cavity. The insulating layer can be formed from BT (bismaleimide-triazine) resin or FR-4 fiberglass reinforced epoxy resin.

The upper surface of the substrate 210 is provided with a plurality of solder pads 213 formed at the periphery of the recessed cavity. Each solder pad 213 is provided with a solder ball 214 for making an electrical connection to an external printed circuit board. The substrate 210 typically includes dielectric layers (e.g. prepreg) and conductive circuit patterns (formed from copper foil) arranged alternately on the reinforcement-containing insulating layer 211. Therefore, the chip contact pads 212 are electrically connected to the solder pads 213 on the upper surface of the substrate through a plurality of conductive traces formed on the surface of the insulating layers 211 and in the conductive circuit patterns.

Although the substrate 210 in this embodiment has four layers of conductive circuit patterns, the total number of layers of the conductive circuit patterns, can be as desired, but generally four or more layers of conductive circuit patterns are utilized. Usually, electrical connection to the different layers of conductive circuit patterns is achieved by drilling via holes and providing conductive material in the via holes.

As shown in FIG. 2, the semiconductor chip 220 is mechanically and electrically interconnected to the chip contact pads 212 on the substrate 220 via a plurality of solder joints 222. Since there is a significant difference between the substrate 210 and the semiconductor chip 220 in coefficient of thermal expansion (CTE) (a semiconductor chip typically has a CTE of about 3-5 parts per million per degree Celsius (ppm/° C.) while a substrate typically has a CTE of about 20-30 ppm/° C.), an underfill 230 is preferably provided between the substrate 210 and the semiconductor chip 220 for sealing voids formed among the solder joints 222. The underfill 230 provides stress relief in the solder joints 222 wherein the stress is caused by CTE mismatch between the semiconductor chip 220 and substrate 210.

It can be understood that the semiconductor chip can also be mechanically and electrically interconnected to the chip contact pads on the insulating layer of the substrate via column-like solder bumps or anisotropic conductive adhesive film (ACF). Further, the substrate according to the present invention can be a laminate type substrate or a multilayer substrate formed by any of a number of build-up technologies (e.g. conformal mask self-limited drilling technique or photo-via technique).

Moreover, the flip chip package according to the present invention may further include a heat sink 240 attached to the backside surface of the semiconductor chip 220 via an adhesive layer of a material with good thermoconductivitity whereby the heat generated from the semiconductor chip can be rapidly dissipated to outside environment through the heat sink thereby enhancing the thermal performance of the package 200.

FIG. 3 illustrates a flip chip package 300 according to another embodiment of the present invention. The flip chip package 300 is characterized by having a metal coating (e.g. a gold plating layer) formed on the lower surface of the substrate 210 (i.e. the surface of the reinforcement containing insulating layer 211), and a plurality of conductive vias 320 formed through the insulating layer 211. Heat generated from the semiconductor chip can be conducted to the metal coating through the conductive vias 320, and then dissipated to outside environment through the metal coating 310 thereby enhancing the thermal performance of the package.

As shown in FIG. 2 and FIG. 3, in the flip chip packages 200 and 300 of the present invention, the conductive traces for electrically connecting the chip contact pads 212 to the solder pads 213 are all formed on the same side of the reinforcement-containing insulating layer 211. Therefore, the flip chip package of the present invention doesn't need to be provided with have plated through-hole in the insulating layer 211 thereby reducing the length of the conductive traces required in the substrate so as to improve the electrical performance of the final package. Moreover, the pattern density of the substrate according to the present invention is not limited by the plated through-holes thereby increasing the degree of freedom in designing the substrate circuit layout.

Although the invention has been explained in relation to its preferred embodiment, it is to be understood that many other possible modifications and variations can be made without departing from the spirit and scope of the invention as hereinafter claimed.

What is claimed is:

1. A flip chip package comprising:
a substrate having an upper surface and a lower surface, the substrate comprising:
a recessed cavity defined in the upper surface of the substrate;
a reinforcement-containing insulating layer;
a plurality of chip contact pads formed on the surface of the reinforcement-containing insulating layer and exposed from the recessed cavity; and
a plurality of solder pads formed on the upper surface of the substrate and outside the recessed cavity for making external electrical connections,
wherein the chip contact pads are electrically connected to the solder pads; and
a semiconductor chip disposed in the recessed cavity of the substrate by flip chip bonding and electrically connected to the chip contact pads.

2. The flip chip package as claimed in claim 1, wherein the semiconductor chip is mechanically and electrically interconnected to the chip contact pads of the substrate via solder joints.

3. The flip chip package as claimed in claim 2, further comprising an underfill formed between the semiconductor chip and substrate.

4. The flip chip package as claimed in claim 1, further comprising a metal coating formed on the lower surface of the substrate and a plurality of conductive vias formed through the reinforcement-containing insulating layer.

5. The flip chip package as claimed in claim 1, further comprising a heat sink disposed on the backside surface of the semiconductor chip.

6. The flip chip package as claimed in claim 1, wherein the reinforcement-containing insulating layer is formed from BT (bismaleimide-triazine) resin.

7. The flip chip package as claimed in claim 1, wherein the reinforcement-containing insulating layer is formed from FR-4 fiberglass reinforced epoxy resin.
